(19) United States
(12) Patent Application Publication
(10) Pub. No.: US 2025/0336763 A1
(43) Pub. Date: Oct. 30, 2025

(54) COOLING APPARATUS FOR DISSIPATING HEAT IN AN ELECTRONIC DEVICE

(71) Applicant: Sandisk Technologies, Inc., Milpitas, TX (US)

(72) Inventors: Hussam Zebian, Milpitas, CA (US); Toshiki Hirano, San Jose, CA (US)

(21) Appl. No.: 18/649,558

(22) Filed: Apr. 29, 2024

(51) Int. Cl. H01L 23/427; H05K 7/20

(52) U.S. Cl. CPC H01L 23/427; H05K 7/20336

(57) ABSTRACT

A cooling apparatus directly contacting an electronic component includes a cooling fluid disposed within an internal cavity defined by a bottom wall and a plurality of sidewalls, and a heat resistance component positioned adjacent to the cooling fluid. The heat resistance component is aligned with the electronic component, and the bottom wall is positioned between the heat resistance component the electronic component. During operation of cooling apparatus, the heat resistance component increases a heat or temperature threshold for the portion of the bottom wall covered by the heat resistance component. The increased temperature threshold for the portion of the bottom wall optimizing the cooling process by reducing or eliminating the risk of film boiling for the cooling fluid, while also allowing more of the cooling fluid to be heated to a temperature that causes evaporation within the cooling apparatus.

### BACKGROUND

Electronic devices often include internal cooling systems that are used to cool various components of the device. Specifically, conventional electronic devices include vapor chambers or heat pipes that receive the generated heat or power from electronic components and expel the heat to the ambient air surrounding the electronic device. For example, heat generated by the electronic component is applied to a vapor chamber, and a cooling liquid formed in the vapor chamber is converted from liquid-phase to a vapor-phase based on the applied heat. The vapor subsequently moves through the chamber, is cooled, and ultimately condenses back to its liquid-phase. The heat stored in the vapor is expelled from the cooling liquid during a condensation phase, and is ultimately expelled from the vapor chamber into the ambient air surrounding the vapor chamber and/or directly out of the electronic device including the vapor chamber.

Although capable of cooling electronic components within the electronic device, conventional cooling systems are not without their faults or operational difficulties. For example, the cooling liquid included within conventional cooling systems includes a maximum or critical heat temperature. When the cooling liquid is heated to near, equal, or beyond the critical heat temperature, film boiling occurs. Film boiling is a phenomenon in which a vapor barrier is formed between a surface supplying heat and the cooling liquid configured to receive the heat during the cooling process. The vapor barrier prevents the liquid from vaporizing and subsequently being condensed by rising through the vapor chamber. Alternatively, in vapor chambers that use wicking for fluid return the prevention of liquid from vaporizing occurs at the onset of bubble formation or when the wick component dries—which is typically earlier than the conventional film boiling regime in a pool of liquid. This phenomenon is referred to as dryout.

Without the constant process of vaporizing and subsequently condensing the cooling liquid within the vapor chamber, a minimal amount of heat is dissipated or expelled from the vapor chamber and the electronic component generating the heat cannot be cooled. Conversely, where the heat generated by the electronic component is not great enough to cause the cooling liquid to evaporate (and subsequently condense) within the vapor chamber, a minimal amount of heat is also expelled from the vapor chamber and the electronic component cannot be cooled. Without proper cooling of the electronic components included in the electronic device, operational performance of the electronic component degrades over time or can even become damaged and inoperable due to the prolonged exposure to the internally generated heat.

Accordingly, it would be beneficial for a cooling system or apparatus of an electronic device to more effectively and efficiently cool components included therein. More specifically, it would be beneficial for a cooling apparatus to be able to evaporate more cooling fluid during the cooling process without increasing the risk of heating the cooling fluid to a threshold that creates a film boiling effect or dryout within the cooling apparatus.

### BRIEF DESCRIPTION

The present disclosure generally relates to electronic devices, and more particularly, to a cooling apparatus for cooling electronic components within the electronic devices.

In an example, the cooling apparatus includes a heat resistance component that is positioned within a cavity of the apparatus. The cavity of the apparatus contains a cooling fluid that at least partially surrounds the heat resistance component. The heat resistance component is also positioned and aligned with the electronic component being cooled by the cooling apparatus. The heat resistance component (artificially) increases a critical heat or temperature threshold for a portion of the housing (e.g., a bottom wall) directly contacting and conducting the heat emitted by the electronic component. By increasing the heat or temperature threshold for the portion of the housing, the heat resistance component can ensure that once the heat travels through the housing of the apparatus and begins to heat the cooling fluid provided therein, the cooling fluid is not heated to a temperature near or above a predetermined critical temperature threshold. Heating the cooling fluid above the predetermined critical temperature threshold can result in the cooling fluid undergoing an undesirable film boiling or dryout process, which in turn reduces the efficiency of heat transfer and/or the cooling of the electronic component. The heat resistance component is also only positioned over a portion of the housing of the apparatus that experiences the highest heat and/or thermal exposure from the electronic component. Distinctly positioning the heat resistance component within the apparatus, as well as forming the heat resistance component with a predetermined size, also ensures that cooling fluid positioned within the cavity adjacent to the heat resistance component is provided with enough heat to cause a desired evaporation effect.

In another example, the cooling apparatus includes a plurality of distinct cavities positioned above and aligned with the electronic component, or alternatively above and adjacent to the electronic component. Each distinct cavity can include cooling fluid and a predetermined pressure. For example, an inner cavity positioned above and aligned with the electronic component can include a first internal pressure, and an outer cavity surrounding the inner cavity, and positioned adjacent the electronic component, can include a second internal pressure, lower than the first internal pressure. The higher the pressure within the cavity, the higher the predetermined critical temperature threshold and the higher the boiling/evaporation temperature for the cooling fluid disposed therein. In the example, the first cavity can include the higher pressure, because it is exposed to and/or experiences the greatest heat or thermal exposure from the electronic component. Conversely, the second cavity experiences less heat or thermal exposure from the electronic component because of its distance relative to the component. Adjusting the pressure within the cavities relative to its proximity to the electronic component can ensure the cooling fluid is not heated to a temperature near or above the predetermined critical temperature threshold, and also ensure the temperature is not well below the boiling/evaporation temperature such that evaporation of the cooling fluid does not occur during the cooling process.

Accordingly, examples of the disclosure provide a cooling apparatus contacting an electronic component of an electronic device. The cooling apparatus is utilized to cool the electronic component and, in an example, can include a bottom wall directly contacting the electronic component, and a plurality of sidewalls formed perpendicular to the bottom wall. The bottom wall and the plurality of sidewalls define an internal cavity. In an example, the cooling apparatus can also include a cooling fluid disposed within the internal cavity, and a heat resistance component positioned adjacent the cooling fluid and aligned with the electronic component. Further in an example, the bottom wall is positioned between the heat resistance component and the electronic component.

Additional examples of the disclosure provide another cooling apparatus contacting an electronic component of an electronic device. The cooling apparatus can include a bottom wall directly contacting the electronic component and a plurality of exterior sidewalls formed perpendicular to the bottom wall. In an example, the cooling apparatus also includes a plurality of interior walls formed perpendicular to the bottom wall and surrounded by the plurality of exterior sidewalls, and an inner cavity defined by the plurality of interior walls and the bottom wall. The inner cavity is directly aligned with and/or positioned above the electronic device the cooling apparatus is contacting and configured to cool. In an example, the cooling apparatus can also include an outer cavity defined by the plurality of exterior sidewalls and the bottom wall, where the outer cavity surrounding the inner cavity, and cooling fluid disposed within the inner cavity and the outer cavity.

Further examples of the disclosure provide a cooling apparatus including a bottom wall directly contacting the electronic component, and a plurality of sidewalls formed perpendicular to the bottom wall, where the plurality of sidewalls and the bottom wall define an internal cavity. In an example the apparatus can also include a means for increasing heat resistance for the bottom wall aligned with the electronic component. The bottom wall is positioned between the means for increasing heat resistance and the electronic component. The cooling apparatus can also include cooling means disposed over the bottom wall and positioned within the internal cavity.

The illustrative aspects of the present disclosure are designed to solve the problems herein described and/or other problems not discussed.

### BRIEF DESCRIPTION OF THE DRAWINGS

These and other features of this disclosure will be more readily understood from the following detailed description of the various aspects of the disclosure taken in conjunction with the accompanying drawings that depict various examples of the disclosure, in which:

FIG. 1 shows a perspective view of a cooling apparatus contacting a heat-generating component of an electronic device, according to an example.

FIG. 2 shows a front cross-sectional view of the cooling apparatus of FIG. 1 taken along line 2-2, the cooling apparatus including a heat resistance component formed as a patch, according to the example.

FIGS. 3-5 show front cross-sectional views of the cooling apparatus including the heat resistance component formed as the patch, according to various examples.

FIG. 6 shows a front cross-sectional view of the cooling apparatus including the heat resistance component formed as a layer of paint, according to another example.

FIG. 7 shows a front cross-sectional view of the cooling apparatus including the heat resistance component formed as a combination of a patch and a layer of paint, according to an additional example.

FIGS. 8 and 9 show front cross-sectional views of the cooling apparatus including the heat resistance component formed as a patch embedded into a bottom wall of the apparatus, according to various examples.

FIG. 10 shows a front cross-sectional view of the cooling apparatus including the heat resistance component formed as an air gap formed directly in a bottom wall of the apparatus, according to an additional example.

FIG. 11 shows a perspective view of a cooling apparatus contacting a heat-generating component of an electronic device, according to a further example.

FIG. 12 shows a front cross-sectional view of the cooling apparatus of FIG. 11 taken along line 12-12, the cooling apparatus including multiple internal cavities, according to the example.

FIG. 13 shows a front cross-sectional view of the cooling apparatus including multiple internal cavities, according to an additional example.

FIG. 14 shows a front cross-sectional view of the cooling apparatus including multiple internal cavities and a heat resistant component, according to a further example.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As an initial matter, in order to clearly describe the current disclosure, it will become necessary to select certain terminology when referring to and describing relevant components within the disclosure. When doing this, if possible, common industry terminology will be used and employed in a manner consistent with its accepted meaning. Unless otherwise stated, such terminology should be given a broad interpretation consistent with the context of the present application and the scope of the appended claims. Those of ordinary skill in the art will appreciate that often a particular component may be referred to using several different or overlapping terms. What may be described herein as being a single part may include and be referenced in another context as consisting of multiple components. Alternatively, what may be described herein as including multiple components may be referred to elsewhere as a single part.

As discussed herein, the disclosure relates to electronic devices, and more particularly, to a cooling apparatus for cooling specified electronic components within electronic devices. In an example, the cooling apparatus includes a heat resistance component that is positioned within a cavity of the apparatus containing a cooling fluid. The heat resistance component is also positioned and aligned with the electronic component being cooled by the cooling apparatus. The heat resistance component (artificially) increases a heat or temperature threshold for a portion of the housing (e.g., bottom wall) directly contacting and conducting the heat emitted by the electronic component. In another example, the cooling apparatus can include a plurality of distinct cavities positioned above and aligned with the electronic component, or alternatively above and adjacent to the electronic component. Each distinct cavity can include cooling fluid disposed therein, and a predetermined pressure. For example, an inner cavity positioned above and aligned with the electronic component can include a first internal pressure, and an outer cavity surrounding the inner cavity, and positioned adjacent the electronic component, can include a second internal pressure, lower than the first internal pressure.

Forming the cooling apparatus to include a heat resistance component and/or distinct, internal cavities having predetermined pressures optimizes the cooling process performed on the electronic component. For example, the inclusion of heat resistance components and/or distinct, internal cavities ensures that once the heat travels through the housing of the apparatus and begins to heat the cooling fluid provided therein, the cooling fluid is not heated to a temperature near or above a predetermined critical heat or temperature threshold-which typically results in undesirable film boiling and/or dryout. Additionally, the inclusion of heat resistance components and/or distinct, internal cavities in the cooling apparatus ensures the heat provided to the cooling fluid can heat the cooling fluid to a temperature at or slightly above the boiling/evaporation temperature such that evaporation of the cooling fluid can occur during the cooling process. Film boiling (e.g., non-evaporation of the cooling fluid) and/or dryout of internal wick components within the cooling apparatus negatively affects the cooling process performed by the cooling apparatus, and in turn can negatively impact the operation of the electronic component cooled by the cooling apparatus.

Accordingly, many technical benefits may be realized including, but not limited to, optimizing and improving the transfer of heat between the electronic device and various portions of the cooling apparatus. Specifically, when utilizing a heat resistance component within the cooling apparatus, the heat resistance component increases a heat or temperature threshold for the portion of the housing (e.g., bottom wall) that experiences the largest heat intensity or heat transfer from the electronic device. Having controllable/modifiable parameters (e.g., size, selectable material thermal conductivity properties, etc.) the heat resistance component can be built, formed, and/or adjusted to ensure that heat is transferred to the cooling fluid of the cooling apparatus at a temperature/intensity that creates an optimum amount of water vapor, and in turn improved cooling effect, as discussed herein. When utilizing a plurality of distinct cavities in the cooling apparatus, a cavity aligned with the electronic device and being provided with the largest heat intensity or heat transfer can control the temperature in which water vapor is generated by adjusting the internal pressure of the cavity. As such, adjusting the internal pressure of the cavity aligned with the electronic device can similarly define or determine the temperature in which the cooling fluid creates an optimum amount of water vapor based on the heat intensity or heat transfer of the electronic device. This in turn improves the cooling effect of the electronic device as an increased/optimum amount of cooling fluid is changed to water vapor within the cavity to transfer the heat, as discussed herein.

Additional benefits include, but are not limited to, reducing or eliminating film boiling and/or dryout within the cooling apparatus. The use of either the heat resistance component or internal cavities having predetermined pressures within the cooling apparatus ensures that the cooling fluid of the cooling apparatus creates an increased or optimum amount of water vapor during the cooling process. This in turn also prevents heating the cooling fluid to near or above a predetermined critical heat or temperature threshold, where the critical temperature threshold is associated with the phenomenon of film boiling and/or dryout occurring within conventional cooling apparatuses. Further benefits include, but are not limited to, ensuring enough heat intensity or heat transfer is occurring within the cooling apparatus to form water vapor from the cooling apparatus. Specifically, the heat resistance component formed only over a predetermined portion of the housing of cooling apparatus or the predetermined internal pressures for each distinct cavity of the cooling apparatus ensures the heat transferred to the cooling fluid is at a temperature or intensity that continuously creates water vapor and/or causes a desired evaporation effect of the cooling fluid.

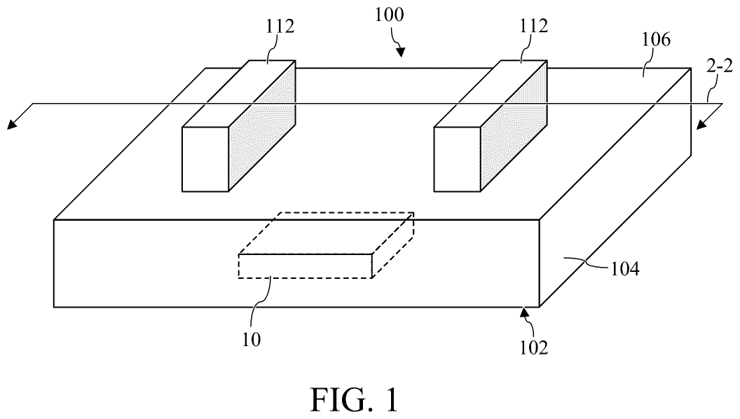

These and other examples are discussed below with reference to FIGS. 1-14. However, those skilled in the art will readily appreciate that the detailed description given herein with respect to these Figures is for explanatory purposes only and should not be construed as limiting.

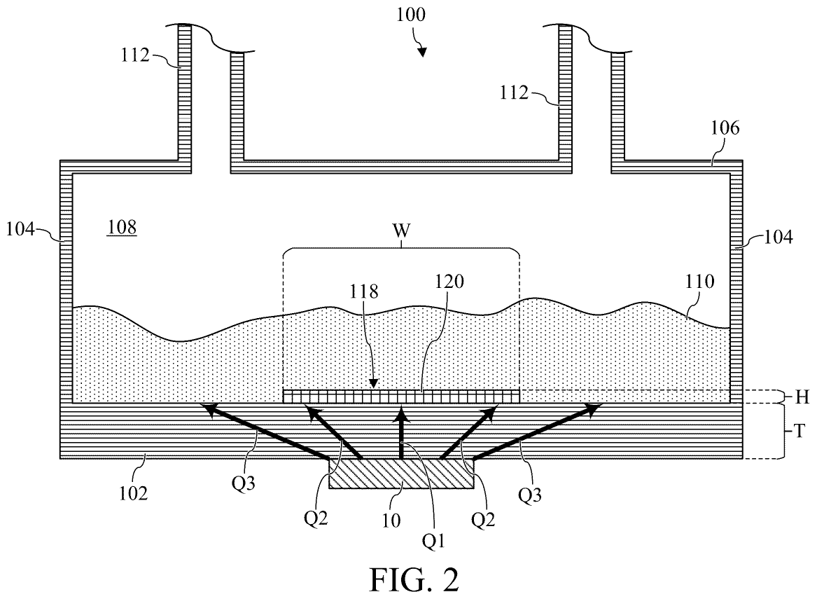

Turning to FIGS. 1 and 2, a cooling apparatus 100 for electronic devices is shown in various views. More specifically, FIG. 1 shows a perspective view of cooling apparatus 100 contacting an electronic component 10 of an electronic device (not shown), and FIG. 2 shows a cross-sectional front view of cooling apparatus 100 taken along line 2-2 in FIG. 1. Electronic component 10 of the electronic device is formed as any internal part, component, and/or system that is utilized for operation of the electronic device and generates heat that needs to be dissipated during operation. For example, electronic component 10 can be formed as a hard disk drive (HDD), a solid-state drive (SSD), a central processing unit (CPU), a graphics processing unit (GPU) or any other suitable component of an electronic device that generates heat and can utilize cooling apparatus 100 for heat dissipation during operation, as discussed herein.

In the non-limiting example, cooling apparatus 100 contacts electronic component 10. More specifically, and as shown in FIGS. 1 and 2, cooling apparatus 100 is positioned directly over, directly above, and directly contacts a surface of electronic component 10. The surface of electronic component 10 in which cooling apparatus 100 contacts includes the surface of electronic component 10 that conducts, generates, and/or produces the greatest amount of heat during operation. As discussed herein, cooling apparatus 100, and the portions/formations therein, is optimally designed to receive and dissipate the heat generated by electronic component 10, and in turn cool and/or maintain electronic component 10 at a desired temperature for ideal performance, and to reduce the risk of operational failure (e.g., shorts, melting, etc.).

As shown in FIG. 2, cooling apparatus 100 includes a bottom wall 102 directly contacting electronic component 10. In the non-limiting example, bottom wall 102 is disposed directly over, directly contacts, and/or is positioned directly on electronic component 10. Bottom wall 102 of cooling apparatus 100 includes a predetermined thickness (T). The predetermined thickness (T) of bottom wall 102 is dependent on, at least in part, the thermal characteristics of electronic component 10, and/or the dimensions of electronic component 10. For example, the predetermined thickness (T) of bottom wall 102 is dependent on the power consumption (W) of electronic component 10, the thermal flux (W/m²)/heat generated by electronic component 10, the surface area (cm²) for cooling electronic component 10, time/duration of operation (and in turn heat generation) by electronic component 10, and/or the overall dimensions (e.g., height, width, depth) of electronic component 10. Additionally, and as discussed herein, the predetermined thickness (T) of bottom wall 102 is dependent on additional components (e.g., heat resistance components) included within cooling apparatus 100.

Cooling apparatus 100 also includes a plurality of sidewalls 104. Each of the plurality of sidewalls 104 are formed substantially perpendicular to bottom wall 102. More specifically, each of the plurality of sidewalls 104 extend from, are formed, and/or oriented substantially perpendicular to bottom wall 102, and each sidewall 104 extends substantially perpendicular to each adjacent/abutting sidewall 104. In the non-limiting example, cooling apparatus 100 includes four sidewalls 104 extending perpendicular from bottom wall 102. However, it is understood that cooling apparatus 100 can include more or fewer sidewalls 104. The number of sidewalls 104, and ultimately the shape of cooling apparatus 100 is dependent, at least in part on, the size/shape of electronic component 10 and/or the allotted space within the electronic device (not shown) that houses and/or receives cooling apparatus 100 and electronic component 10, respectively.

In the non-limiting example shown in FIGS. 1 and 2, cooling apparatus 100 also includes a top wall 106. Top wall 106 is disposed over and/or positioned above the plurality of sidewalls 104, opposite bottom wall 102. Additionally, top wall 106 extends from, is formed, and/or oriented substantially perpendicular to each of the plurality of sidewalls 104 and extends substantially parallel to bottom wall 102. As shown in FIG. 2, bottom wall 102, the plurality of sidewalls 104, and top wall 106 collectively define an internal cavity 108. More specifically, bottom wall 102, sidewalls 104, and top wall 106 define, form, and/or delineate internal cavity 108 of cooling apparatus 100. In the non-limiting example, internal cavity 108 is positioned adjacent and above electronic component 10. Bottom wall 102 of cooling apparatus 100 is positioned between and separates internal cavity 108 and electronic component 10. As discussed herein, internal cavity 108 houses, receives, and/or contains additional components of cooling apparatus 100 that aids in the dissipation of the heat generated by electronic component 10, and ultimately cools electronic component 10 during operation.

As shown in FIG. 2, bottom wall 102, the plurality of sidewalls 104, and top wall 106 of cooling apparatus 100 are integrally formed with one another. That is, bottom wall 102, the plurality of sidewalls 104, and top wall 106 are formed as a single, solitary component, and from a single, uniform material. In other non-limiting examples, bottom wall 102, the plurality of sidewalls 104, and/or top wall 106 are formed from distinct portions that are coupled or affixed to one another prior to positioning cooling apparatus over electronic component 10. In the non-limiting example, bottom wall 102, the plurality of sidewalls 104, and/or top wall 106 can be coupled or affixed to one another using any suitable coupling mechanism and/or technique. In the example where portions of cooling apparatus 100 are integrally formed (e.g., see, FIG. 2), bottom wall 102, the plurality of sidewalls 104, and top wall 106 are formed from a material including high-thermal conductivity properties. For example, bottom wall 102, the plurality of sidewalls 104, and top wall 106 of cooling apparatus 100 are formed from a high-thermal conductivity material including, but not limited to, copper, steel, iron, silver, tungsten, aluminum, brass, or any other material including similar thermal conductivity properties. In the non-limiting example where bottom wall 102, the plurality of sidewalls 104, and/or top wall 106 are distinctly formed and coupled to one another, bottom wall 102 is formed from a material having high-thermal conductivity properties. The plurality of sidewalls 104 and/or top wall 106 can be formed from similar materials as bottom wall 102, or alternatively from materials having lower thermal conductivity and/or insulative properties. As discussed herein, forming bottom wall 102 from a material having high-heat conductivity properties improves the heat transfer from electronic component 10 to cooling apparatus 100, which in turn improves the cooling of electronic component 10.

In the non-limiting example shown in FIG. 2, cooling apparatus 100 also includes cooling fluid 110. Cooling fluid 110 is disposed within internal cavity 108. More specifically, cooling fluid 110 is disposed within internal cavity 108 defined by bottom wall 102, the plurality of sidewalls 104, and top wall 106, respectively. As shown, cooling fluid 110 is also disposed over and/or contacts bottom wall 102 of cooling apparatus 100, such that bottom wall 102 is positioned directly between cooling fluid 110 and electronic component 10. Cooling fluid 110 is formed from any suitable fluid that is capable of evaporating at a predetermined temperature and subsequently condensed within cooling apparatus 100, as discussed herein. In a non-limiting example, cooling fluid 110 disposed within internal cavity 108 is formed as a combination of water and water vapor.

Cooling apparatus 100 also includes at least one heatpipe 112. In a non-limiting example, heatpipe(s) 112 is formed above top wall 106. More specifically, and as shown in FIG. 2, heatpipe(s) 112 is formed above top wall 106, extends through top wall 106, and/or is in fluid communication with internal cavity 108 of cooling apparatus 100. Heatpipe(s) 112 extend beyond cooling apparatus 100 and are positioned adjacent to and/or in communication with the ambient air surrounding the electronic device including cooling apparatus 100 and electronic component 10. As discussed herein, heat dissipated through cooling apparatus is released to the ambient air via heatpipe(s) 112. In the example shown in FIGS. 1 and 2, cooling apparatus 100 includes two distinct heatpipes 112, each formed above top wall 106 and in fluid communication with internal cavity 108. However, it is understood that cooling apparatus 100 can include more or fewer heatpipe(s) 112. For example, cooling apparatus 100 can include a single heatpipe 112 that is formed as a rectangle hollow section (RHS) or square hollow section (SHS), where the RHS/SHS heatpipe 112 is in fluid communication with internal cavity 108.

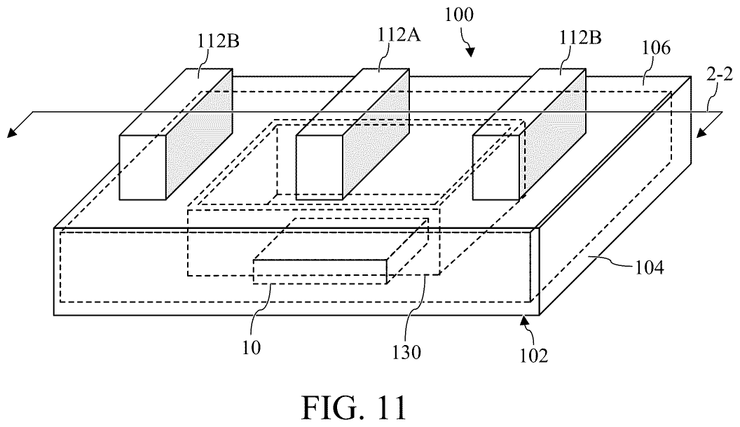

As shown in FIG. 2, cooling apparatus 100 also includes a heat resistance component 118. Heat resistance component 118 is positioned adjacent cooling fluid 110. More specifically, heat resistance component 118 is positioned directly over at least a portion of bottom wall 102, within internal cavity 108, and is substantially surrounded by and/or submerged within cooling fluid 110 disposed within internal cavity 108, such that cooling fluid 110 flows directly over heat resistance component 118. Bottom wall 102 is also positioned between and separates heat resistance component 118 and electronic component 10. Additionally as shown in the non-limiting example of FIG. 2, heat resistance component 118 is disposed and/or positioned directly over bottom wall 102 and substantially aligned with electronic component 10. In the example, a center of heat resistance component 118 is substantially aligned with a center of electronic component 10. Heat resistance component 118 is also positioned proximate to, surrounded by, and/or separated from the plurality of sidewalls 104 of cooling apparatus 100. That is, and dependent upon the position of electronic component 10 with respect to bottom wall 102 (see, FIG. 11), heat resistance component 118 is separated from and/or spaced apart from the plurality of sidewalls 104 to optimize heat transfer from electronic component 10 during the cooling process, as discussed herein. Also as discussed herein, the position and/or alignment of heat resistance component 118 with respect to electronic component 10 is to increase a heat resistance for a portion of cooling apparatus 100 to optimize the cooling of electronic component 10 during operation.

Heat resistance component 118 is utilized within cooling apparatus 100 to improve the cooling of electronic component 10 and/or optimize the heat transfer from electronic component 10, through bottom wall 102, to cooling fluid 110 during the cooling process. As such, heat resistance component 118 is formed from any suitable component and/or material that increases the heat resistance of a portion of bottom wall 102 of cooling apparatus 100 positioned over electronic component 10. In the non-limiting example shown in FIG. 2, heat resistance component 118 is formed as a patch 120 positioned directly over bottom wall 102, within internal cavity 108. Patch 120 is formed from a material and/or component having lower thermal conductivity properties than the material forming bottom wall 102. For example, where bottom wall 102 is formed from copper, heat resistance component 118 configured as patch 120 is formed from aluminum material. In other non-limiting examples, patch 120 can be formed from, but is not limited to, epoxy resins, polymers, steel, iron, silver, tungsten, aluminum, brass, or any other material including similar thermal conductivity properties, so long as the thermal conductivity properties of the material forming patch 120 is lower than the thermal conductivity properties of the material forming bottom wall 102.

As discussed herein, patch 120 forming heat resistance component 118 is positioned directly over and aligned with electronic component 10, as well as formed from a predetermined material to optimize the heat transfer to electronic component 10 during the cooling process. Additionally, patch 120 includes a predetermined shape based on characteristics of electronic component 10 and/or distinct portions of cooling apparatus 100 that aid in the cooling of electronic component 10. For example, patch 120 includes a shape and/or configuration that is substantially similar to the shape of electronic component 10. As shown in FIG. 1, electronic component 10 is formed as a rectangular prism, and includes a surface that contacts cooling apparatus 100 that is substantially square or rectangular in shape. In the non-limiting example, patch 120 is also configured or formed as a rectangular prism and/or includes a two-dimensional reference shape (e.g., top surface) that is square or rectangular.

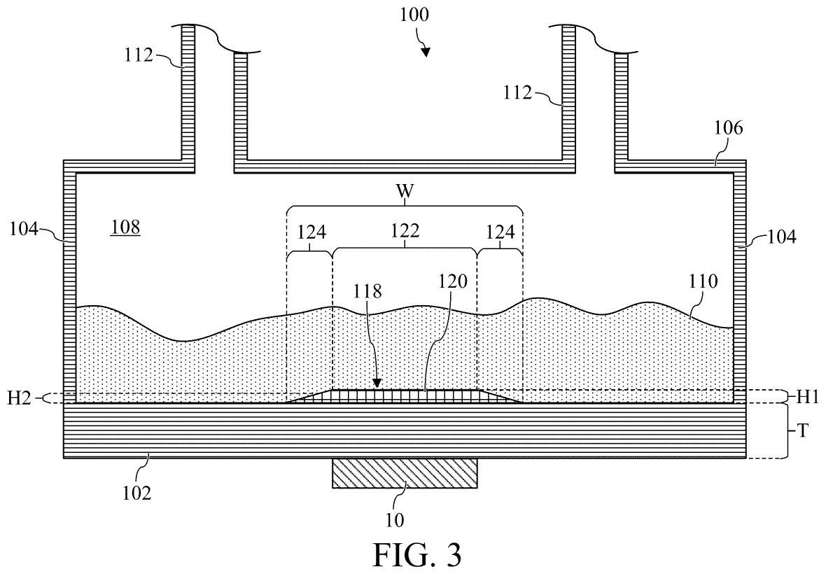

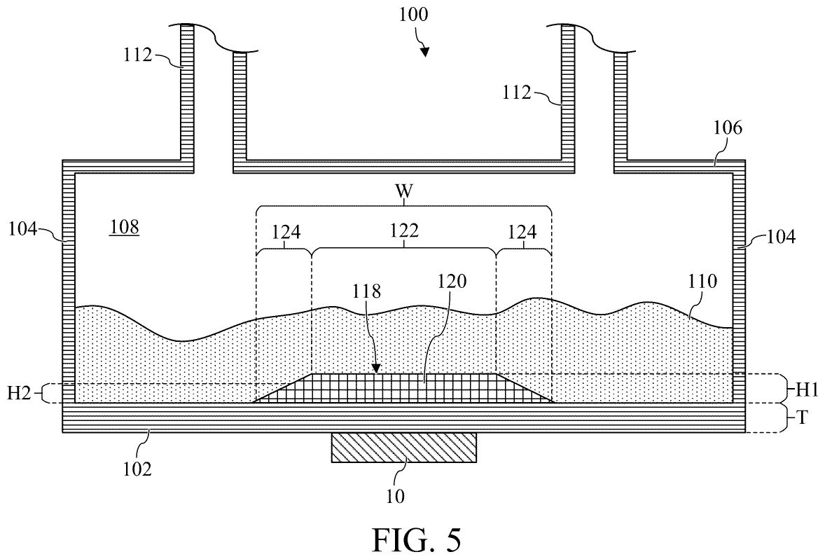

The predetermined size of heat resistance component 118/patch 120 is also based on characteristics of electronic component 10 and/or distinct portions of cooling apparatus 100 to aid in the cooling of electronic component 10, as discussed herein. Specifically, the size or dimensions (e.g., length, width, height/thickness) of heat resistance component 118/patch 120 are based on, at least in part, thermal characteristics of electronic component 10, dimensions of electronic component 10, material characteristics of bottom wall 102, and/or dimensions of bottom wall 102. For example, a height (H) and/or width (W) of patch 120 is based on the heat, temperature, and/or thermal intensity generated by electronic component 10 during operation. In the example, as heat and/or thermal intensity of electronic component 10 increases during operation, so does the height (H) and/or width (W) of patch 120. Other thermal characteristics of electronic component 10 that determine the dimensions and/or size of patch 120 can also include a determined heat signature of electronic component 10 during operation. Additionally, the dimensions of patch 120 can be directly proportional to the dimensions of electronic component 10, such that as the dimensions of electronic component 10 increases, the dimensions of patch 120 can also increase. In examples, all dimensions of patch 120 can increase with larger electronic components 10, or alternatively, only a portion of the dimensions (e.g., only height (H), only width (W), width (W)+length (L)) of patch 120 increase with larger electronic components 10. Material characteristics of bottom wall 102 also influence, at least in part, the predetermined size or dimensions of patch 120. For example, if bottom wall 102 is formed from a material having high thermal conductivity properties (e.g., copper), the height (H) and/or width (W) of patch 120 are larger than the height (H) and/or width (W) of patch 120 included in cooling apparatus where bottom wall 102 is formed from a material having lower thermal conductivity properties (e.g., aluminum). Furthermore, the dimensions (e.g., height (H), width (W), and/or length (L)) of patch 120 are based on, at least in part, the thickness (T) of bottom wall 102. In an example, as the thickness (T) of bottom wall 102 decreases, dimensions of patch 120 increase to optimize the heat transfer to electronic component 10 during the cooling process (compare, FIG. 3 and FIG. 5). Any number or combination of the characteristics of electronic component 10 and/or distinct portions (e.g., bottom wall 102) of cooling apparatus 100 discussed herein are considered when determining the size and/or dimensions of heat resistance component 118/patch 120. As discussed herein, these characteristics, at least in part, influence the size of heat resistance component 118/patch 120, where the predetermined size of patch 120 optimizes heat transfer during the cooling process performed by cooling apparatus 100.

FIG. 2 depicts multiple arrows representing heat (Q) generated by electronic component 10 and conducting through bottom wall 102. Although only five (5) arrows are shown, it is understood that electronic component 10 is emitting a wave or continuous area of heat adjacent to bottom wall 102 during operation, and the number of arrows representing heat (Q) is illustrative. Furthermore, it is understood that heat (Q) generated by electronic component 10 spreads or propagates through nearly all of bottom wall 102. As such, the arrows shown in FIG. 2 representing heat (Q) are illustrative and do not represent an exact location of where heat (Q) is conducted and/or passes through bottom wall 102.

During operation of the electronic device, and in turn the cooling of electronic component 10, heat (Q) generated by electronic component 10 is transferred through cooling apparatus 100. More specifically, heat (Q) generated by electronic component 10 is transferred, passes through, and/or is conducted through bottom wall 102 of cooling apparatus 100 in direct contact/positioned directly adjacent electronic component 10. The heat (Q) passes through, and/or is at least partially absorbed by bottom wall 102, such that bottom wall 102 heats up and/or increases in temperature. Heat (Q) passing through and heating bottom wall 102 is subsequently transferred to cooling fluid 110 disposed within internal cavity 108 of cooling apparatus. When cooling fluid's 110 temperature rises to desired temperature, via the transfer of heat (Q), cooling fluid 110 evaporates and/or forms a cooling fluid vapor that rises within internal cavity 108 and eventually through heatpipes 112. Within heatpipes 112, the cooling fluid vapor is cooled and subsequently condensed back to a liquid, and the condensed, liquid form of cooling fluid 110 is returned to internal cavity 108. The process of creating cooling fluid vapor and subsequently condensing the vapor back to a liquid releases the generated heat (Q) into the ambient air surrounding the electronic device including electronic component 10 and cooling apparatus 100, and ultimately cools and/or maintains electronic component 10 at a desired temperature during operation.

As discussed herein, bottom wall 102 is formed or includes a predetermined thickness (T) that optimizes the cooling process. More specifically, bottom wall 102 is formed with a predetermined thickness (T) that ensures heat (Q) conducted therethrough reaches and is transferred to cooling fluid 110 at a temperature that causes cooling fluid to desirably evaporate/form water vapor. The temperature of the liquid-to-vapor or evaporation occurrence is called the saturation temperature. In some examples, the saturation temperature can change as a function of the heat or thermal flux temperature and/or ambient conditions for cooling apparatus 100. Additionally, bottom wall 102 is formed with the predetermined thickness (T) to avoid or substantially prevent heat (Q) from reaching and subsequently heating cooling fluid 110 to a temperature near or above a critical temperature threshold. Heating cooling fluid 110 near or above the critical temperature threshold can cause undesirably film boiling (or dryout) within cooling apparatus 100, which in turn prevents or reduces the cooling effect cooling apparatus 100 has on electronic component 10 during operation. In the example shown in FIG. 2, bottom wall 102 is formed with the predetermined thickness (T) such that heat (Q3) transferring through bottom wall 102 and reaching cooling fluid 110 adjacent heat resistance component 118/patch 120 is below the critical temperature threshold, and creates cooling fluid vapor, as discussed herein.

However, heat (Q1, Q2) transferred through bottom wall 102 closer to electronic component 10 can reach internal cavity 108 and/or cooling fluid 110 near or above the critical temperature threshold. That is, heat (Q1, Q2) conducted through bottom wall 102 directly above and/or aligned with electronic component 10 reaches internal cavity 108 and/or cooling fluid 110 at a greater thermal temperature and/or intensity than heat (Q3) conducted and/or traveling through bottom wall 102 adjacent to and/or not aligned with electronic component 10. This is due, at least in part, to the smaller distance in which the heat (Q) is conducted and/or traversed through bottom wall 102 to reach internal cavity 108 and/or cooling fluid 110 (e.g., compare Q1/Q2 v. Q3). That is, less heat (Q) is absorbed and/or dissipated within bottom wall 102 when heat (Q) pass through a shorter distance to reach internal cavity 108 and/or cooling fluid 110, as such heat (Q) is most intense directly above and/or in substantial alignment with electronic component 10 (e.g., Q1>Q2>Q3).

As discussed herein, to improve heat/temperature resistance, cooling apparatus 100 includes heat resistance component 118/patch 120. In the non-limiting example shown in FIG. 2, patch 120 is positioned directly on bottom wall 102 and is aligned with electronic component 10, such that the most intense heat (Q1, Q2) passing through bottom wall 102 must also pass through patch 120 before reaching and interacting with cooling fluid 110 disposed over patch 120. Patch 120, formed from a lower heat conductive material than bottom wall 102 subsequently absorbs and/or receives heat (Q1, Q2), and in turn transfers heat (Q1, Q2) to cooling fluid 110 below the critical temperature threshold to create the cooling fluid vapor, as discussed herein. Knowing, calculating, and/or observing thermal characteristics of electronic component 10 (e.g., generated heat (Q), heat signature, etc.), dimensions of electronic component 10, material characteristics of bottom wall 102, and/or predetermined thickness (T) of bottom wall also ensures heat resistance component 118/patch 120 is sized (e.g., height (H), width (W), length (L)) to prevent any heat (Q) from being transferred to the cooling fluid 110 near or above the critical temperature threshold. As such, the inclusion of heat resistance component 118/patch 120 within cooling apparatus can more evenly distribute heat (Q) through bottom wall 102 of cooling apparatus 100 at a desired temperature to optimize, improve, and/or increase the creation of vapor using cooling fluid 110. Additionally, the inclusion of heat resistance component 118/patch 120 within cooling apparatus can reduce or eliminate the risk of creating undesirable film boiling (and/or dryout, where applicable) within cooling apparatus 100.

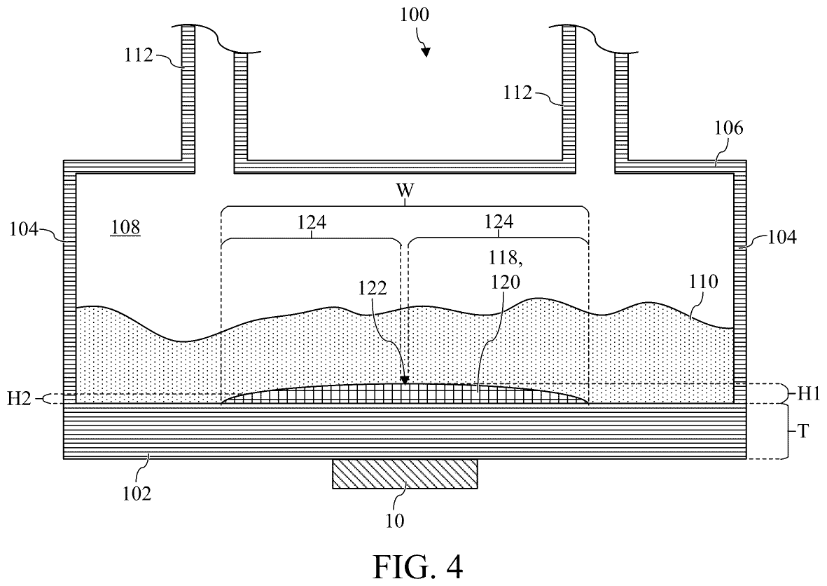

FIGS. 3 and 4 show cross-sectional front views of electronic component 10 and cooling apparatus 100, according to additional examples. It is understood that similarly numbered and/or named components may function in a substantially similar fashion. Redundant explanation of these components has been omitted for clarity and/or brevity.

Turning to FIG. 3, cooling apparatus 100 includes heat resistance component 118 formed as patch 120. In the non-limiting example, patch 120 is positioned directly on bottom wall 102 and includes a first portion 122 in direct alignment with electronic component 10, and a second portion 124 formed adjacent to and/or substantially surrounding first portion 122. Additionally in the example shown, second portion 124 of patch 120 extends beyond the boundaries and/or sides of electronic component 10. First portion 122 includes a first height (H1), and second portion 124 includes a second height (H2), distinct from the first height (H1). More specifically, and as shown FIG. 3, second height (H2) of second portion 124 is less than first height (H1) of first portion 122. Furthermore, second height (H2) of second portion 124 is variable and tapered away from first portion 122, such that second height (H2) decreases within second portion 124 the further away second portion 124 is from first portion 122.

Patch 120 includes distinct heights (H1, H2) to ensure heat (Q) transferred and/or conducted through bottom wall 102 does interact with cooling fluid 110 at an undesirably low temperature so evaporation or the creation of cooling fluid vapor cannot occur. As discussed herein with respect to FIG. 2, the further the heat (Q) travels through bottom wall 102, the more heat is absorbed within bottom wall 102. Additionally, heat (Q) reaching portions of patch 120 adjacent to, but not directly aligned with, electronic component 10 (e.g., second portion 124) requires less heat resistance than heat (Q) conducted through portions of patch 120 directly aligned with electronic component 10 (e.g., first portion 122). As such, second portion 124 includes the second height (H2) that is smaller than the first height (H1) because less heat resistance is needed in the area of bottom wall 102 covered by second portion 124 and/or there is less of a risk of heat (Q) reaching and subsequently heating cooling fluid 110 to a temperature near or above a critical temperature threshold.

Similar to the non-limiting example shown in FIG. 3, FIG. 4 shows patch 120 including a first portion 122 and second portion 124 formed adjacent to and substantially surrounding first portion 122. Also similar to the example shown in FIG. 3, second portion 124 of patch 120 includes a tapered or variably diminishing second height (H2) that is smaller the further second portion 124 is formed from first portion 122. That is, and as is shown in FIG. 4, patch 120 is formed or configured as a dome, where first portion 122 includes an apex of the dome, and second portion 124 substantially surrounds the first portion 122. First portion 122 (e.g., apex) includes the first height (H1) that is larger than the second height (H2) of second portion 124. For similar reasons provided herein with respect to patch 120 shown in FIG. 3, less heat/thermal resistance is needed in areas of bottom wall 102 covered by second portion 124. As such, second portion 124 includes a second height (H2) that is lower or smaller than the first height (H1) of first portion 122 of patch 120.

FIG. 5 depicts another non-limiting example of cooling apparatus 100 that includes a heat resistance component 118 formed as patch 120. Briefly returning to FIG. 3, bottom wall 102 of cooling apparatus 100 shown in FIG. 5 includes a smaller thickness (Ts) than the thickness (T) of distinct bottom walls 102 discussed herein. As such, not as much heat (Q) conducted and/or passing through bottom wall 102 is absorbed and/or dissipated within bottom wall 102. In this example, the heat (Q) reaching not just directly above and aligned with electronic component 10, but heat (Q) passing through portions of bottom wall 102 adjacent to electronic component 10, can be near or above the critical temperature threshold. To reduce or eliminate the risk of film boiling (and/or dryout, where applicable), the predetermined size of heat resistance component 118/patch 120 is increased. Specifically, and as shown in the non-limiting example of FIG. 5, the height (H1, H2) and width (W) of patch 120 is larger than other patches 120 discussed herein (e.g., see, FIG. 3), when thickness (Ts) of bottom wall 102 is smaller. The larger size of patch 120 adds the desired heat/thermal resistance to prevent heat (Q) reaching and subsequently heating cooling fluid 110 to a temperature near or above a critical temperature threshold.

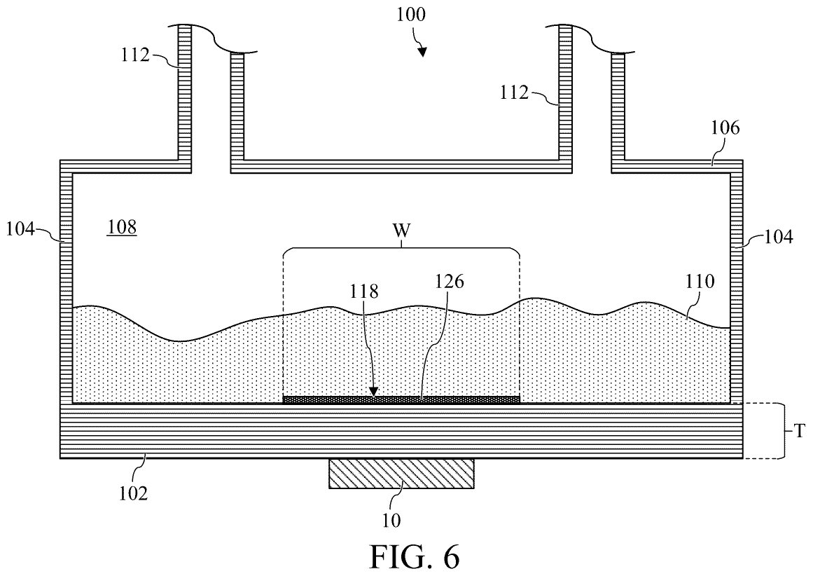

FIG. 6 shows a cross-sectional front view of electronic component 10 and cooling apparatus 100, according to another example. It is understood that similarly numbered and/or named components may function in a substantially similar fashion. Redundant explanation of these components has been omitted for clarity and/or brevity.

In FIG. 6, heat resistance component 118 is formed as a heat resistant paint 126. More specifically, rather than a patch, cooling apparatus 100 can include at least one layer of heat resistant paint 126 to form heat resistance component 118. Heat resistant paint 126 is disposed directly on and/or over bottom wall 102. Additionally as shown, heat resistant paint 126 is positioned over and/or substantially aligned with electronic component 10 to increase the heat/thermal resistance of a portion of bottom wall 102 positioned directly above (and directly adjacent) to electronic component 10, as similarly discussed herein. Similar to patch 120, a predetermined size (e.g., length (L), width (W)) and/or number of layers of heat resistant paint 126 included in cooling apparatus 100 is dependent on, at least in part, thermal characteristics of electronic component 10, dimensions of electronic component 10, material characteristics of bottom wall 102, and/or dimensions of bottom wall 102. Heat resistant paint 126 includes any suitable paint or paintable material that increases the heat/thermal resistance of a portion of bottom wall 102, as discussed herein. For example, heat resistant paint 126 is formed from an epoxy-based resin paint or any polymer suitable coating.

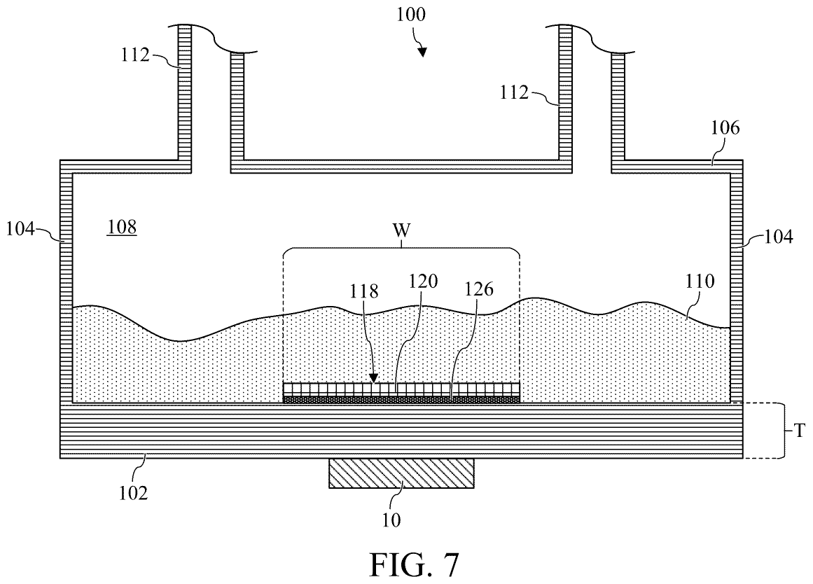

FIG. 7 shows a non-limiting example of cooling apparatus 100 utilizing more than one heat resistance component 118. Specifically, cooling apparatus 100 shown in FIG. 7 includes heat resistant paint 126 disposed directly over bottom wall 102, and patch 120 positioned directly over and/or directly on heat resistant paint 126. In the example, both heat resistant paint 126 and patch 120 forming heat resistance component 118 are positioned above and in substantially alignment with electronic component 10. Although shown in FIG. 7 as including identical widths, it is understood that patch 120 can include a smaller width than heat resistant paint 126. As such, heat (Q) traveling through bottom wall 102 central to electronic component 10 will also pass through both heat resistant paint 126 and patch 120, while heat (Q) traveling through bottom wall 102 adjacent to, and not aligned with, electronic component 10 will only pass through heat resistant paint 126.

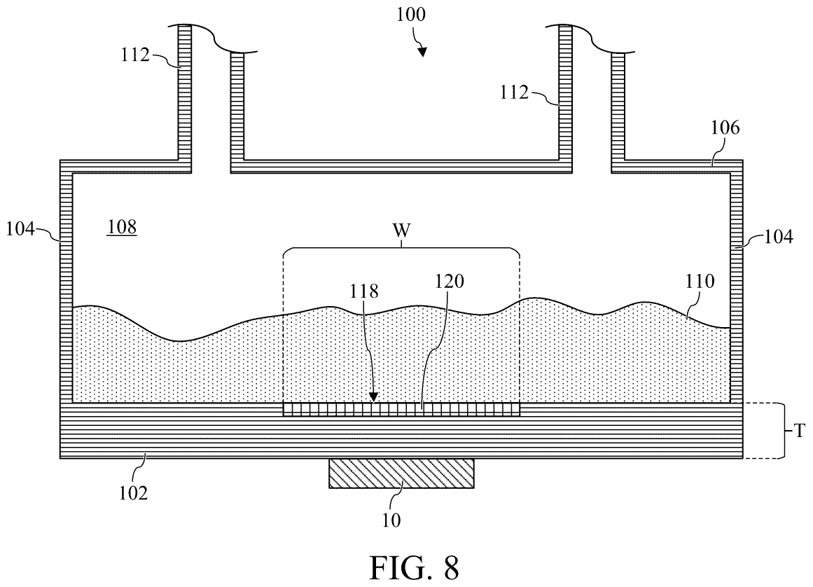

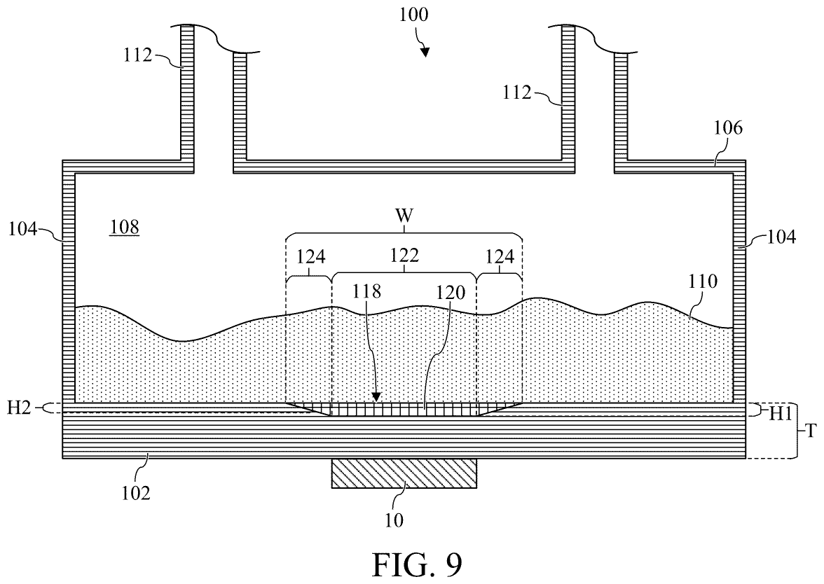

FIGS. 8 and 9 show cross-sectional front views of electronic component 10 and cooling apparatus 100, according to further examples. It is understood that similarly numbered and/or named components may function in a substantially similar fashion. Redundant explanation of these components has been omitted for clarity and/or brevity.

In the non-limiting examples shown in FIGS. 8 and 9, heat resistance component 118 is formed in bottom wall 102. More specifically, and distinct from be positioned or disposed on (see, FIGS. 2-7), heat resistance component 118 of cooling apparatus 100 is formed in and/or directly embedded within bottom wall 102, opposite to and aligned with electronic component 10. In the examples, a portion of bottom wall 102 positioned directly above (and directly adjacent to) electronic component 10 includes a trench configured to receive heat resistance component 118 therein. As a result of embedding heat resistance component 118 directly within bottom wall 102, heat resistance component 118 and bottom wall 102 are substantially planar to one another. Heat resistance component 118 embedded within bottom wall 102 is also positioned directly adjacent internal cavity 108 of cooling apparatus 100, and the combination of bottom wall 102 and heat resistance component 118 collectively define at least a portion of internal cavity 108. In the non-limiting example shown in FIG. 8, heat resistance component 118 is formed as patch 120, including a uniform height (H). Alternatively, in the example shown in FIG. 9, heat resistance component 118/patch 120 embedded directly within bottom wall 102 includes first portion 122 and second portion 124, where second height (H2) of second portion 124 is tapered away from first portion 122, similar to patch 120 discussed herein with respect to FIG. 3. As similarly discussed herein, the predetermined shape and/or size of heat resistance component 118/patch 120 embedded within bottom wall 102 is based on, at least in part, thermal characteristics of electronic component 10, dimensions of electronic component 10, material characteristics of bottom wall 102, and/or dimensions of bottom wall 102.

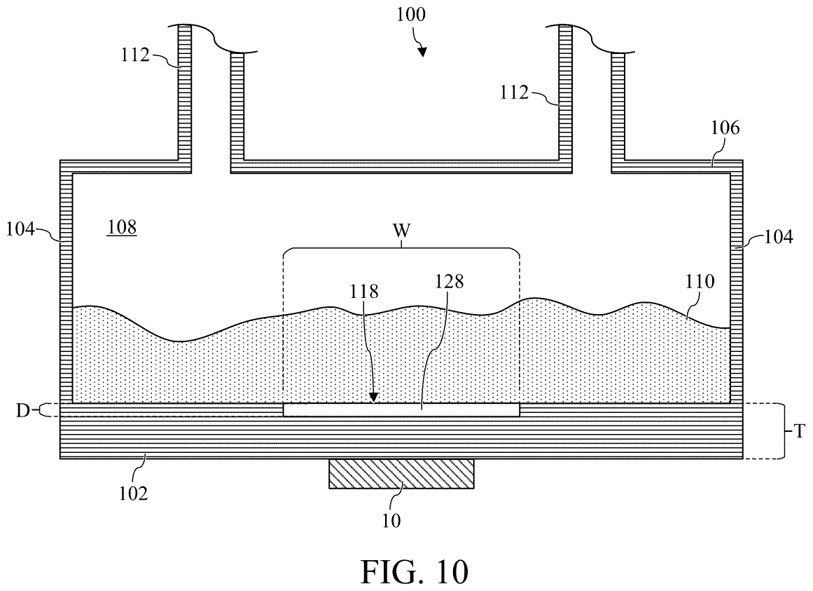

As discussed herein, heat resistance component 118 includes heat conductivity properties that are lower than heat conductivity properties of the material forming bottom wall 102 to increase the heat resistance of portions of bottom wall 102. For example, air includes heat conductivity properties lower than example materials (e.g., copper, aluminum, etc.) used to form bottom wall 102 of cooling apparatus 100. As shown in FIG. 10, heat resistance component 118 includes or is formed as an air gap 128. Specifically, air gap 128 is formed directly within bottom wall 102 of cooling apparatus 100, and is substantially aligned with electronic component 10, such that a portion of bottom wall 102 separates air gap 128 and electronic component 10. Air gap 128 is also formed within bottom wall 102 directly adjacent to internal cavity 108 of cooling apparatus 100. Similar to other examples of heat resistance component 118 (e.g., patch 120), the predetermined shape and/or size of air gap 128 embedded within bottom wall 102 is based on, at least in part, thermal characteristics of electronic component 10, dimensions of electronic component 10, material characteristics of bottom wall 102, and/or dimensions of bottom wall 102.

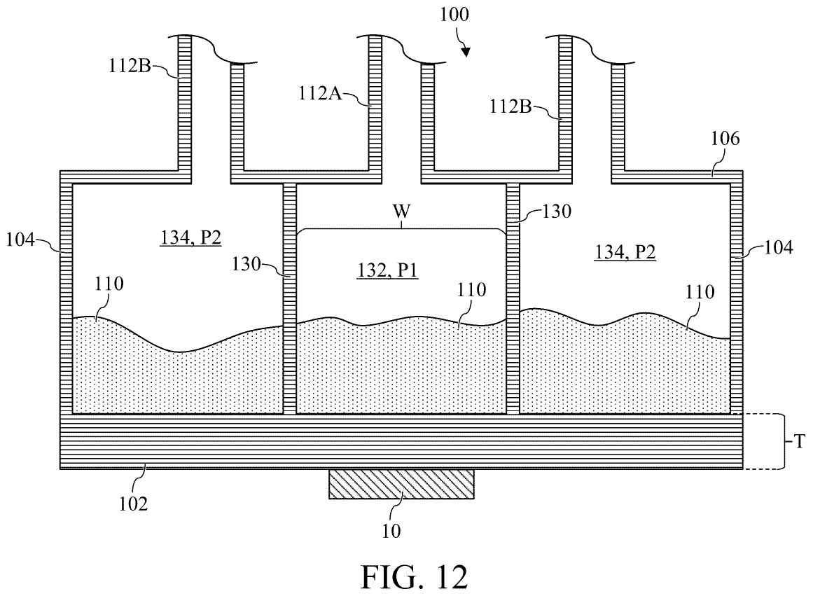

Turning to FIGS. 11 and 12, another non-limiting example of cooling apparatus 100 for electronic devices is shown in various views. More specifically, FIG. 11 shows a perspective view of cooling apparatus 100 contacting electronic component 10 of an electronic device (not shown), and FIG. 12 shows a cross-sectional front view of cooling apparatus 100 taken along line 12-12 in FIG. 11. As discussed herein, cooling apparatus 100 shown in FIGS. 11 and 12 include a plurality of internal walls that separate internal cavity 108 into distinct cavities for optimally cooling electronic component 10. It is understood that similarly numbered and/or named components may function in a substantially similar fashion. Redundant explanation of these components has been omitted for clarity and/or brevity.

In the non-limiting example shown in FIGS. 11 and 12, cooling apparatus 100 includes a plurality of interior walls 130 (shown in phantom in FIG. 11). Each of the plurality of interior walls 130 are formed substantially perpendicular to bottom wall 102. More specifically, each of the plurality of interior walls 130 extend from, are formed between, and/or oriented substantially perpendicular to bottom wall 102 and top wall 106, and each interior wall 130 extends substantially perpendicular to each adjacent/abutting interior wall 130. Additionally, the plurality of interior walls 130 are surrounded by the plurality of exterior sidewalls 104 of cooling apparatus 100. In the non-limiting example, cooling apparatus 100 includes four interior walls 130, each formed adjacent to a corresponding sidewall 104 and oriented substantially parallel to the adjacent sidewall 104. However, it is understood that cooling apparatus 100 can include more or fewer interior walls 130. The number of interior walls 130 is dependent, at least in part on, the size/shape of electronic component 10 and/or the allotted space within the electronic device (not shown) that houses and/or receives cooling apparatus 100 and electronic component 10, respectively. Additionally, it is understood that cooling apparatus can include more or fewer interior walls 130 than sidewalls 104.

Similar to bottom wall 102, the plurality of sidewalls 104, and top wall 106, interior walls 130 of cooling apparatus 100 are integrally formed with other portions of cooling apparatus 100. That is, and as shown in FIG. 12, bottom wall 102, the plurality of sidewalls 104, top wall 106, and interior walls 130 are formed as a single, solitary component, and from a single, uniform material. In other non-limiting examples, bottom wall 102, the plurality of sidewalls 104, top wall 106, and/or interior sidewalls 130 are formed from distinct portions that are coupled or affixed to one another prior to positioning cooling apparatus 100 over electronic component 10. In the non-limiting example, bottom wall 102, the plurality of sidewalls 104, top wall 106, and/or interior walls 130 can be coupled or affixed to one another using any suitable coupling mechanism and/or technique. Also similar to bottom wall 102, the plurality of sidewalls 104, and top wall 106, interior walls 130 are formed from a material including high-thermal conductivity properties.

Interior walls 130 of cooling apparatus 100 define distinct cavities 132, 134 in cooling apparatus 100. That is, cooling apparatus 100 including interior walls 130 divide an internal cavity 108 (e.g., see FIG. 2) into a plurality of distinct cavities 132, 134 for cooling apparatus 100. In the non-limiting example shown in FIG. 12, an inner cavity 132 is defined by the plurality of interior walls 130, bottom wall 102, and top wall 106. Inner cavity 132 is formed, positioned, and/or in direct alignment with electronic component 10 contacting bottom wall 102. Similar to internal cavity 108 discussed herein, cooling fluid 110 is disposed within inner cavity 132 of cooling apparatus 100 and is used to cool electronic component 10. Additionally as shown in FIG. 12, inner cavity 132 is in fluid communication with a first heatpipe 112A, where first heatpipe 112A receives fluid vapor and subsequently aids in the condensing of the vapor back to the liquid, cooling fluid, as similarly discussed herein.

Cooling apparatus 100 shown in FIGS. 11 and 12 also includes an outer cavity 134. Outer cavity 134 is formed adjacent inner cavity 132. More specifically, outer cavity 134 is positioned adjacent to and substantially surrounds inner cavity 132, and the plurality of interior walls 130 are positioned between and separate inner cavity 132 and outer cavity 134 of cooling apparatus 100. In the non-limiting example, outer cavity 134 is defined by bottom wall 102, exterior sidewalls 104, a portion of top wall 106, and interior walls 130. Cooling fluid 110 is also disposed within outer cavity 134 of cooling apparatus 100 and is used to cool electronic component 10. Additionally, outer cavity 134 is in fluid communication with a second heatpipe(s) 112B. In the non-limiting example shown in FIGS. 11 and 12, two distinct, second heatpipes 112B are formed through top wall 106, opposite one another, and are both in fluid communication with outer cavity 134. In other non-limiting examples discussed herein, second heatpipe 112B can be formed as a continuous rectangle hollow section (RHS) or square hollow section (SHS), where the RHS/SHS heatpipe 112B is in fluid communication with outer cavity 134. Similar to first heatpipe 112A, second heatpipe(s) 112B receives fluid vapor and subsequently aids in the condensing of the vapor back to the liquid, cooling fluid 110 disposed within outer cavity 134 for cooling electronic component 10.

As discussed herein, inner cavity 132 is positioned directly over and aligned with electronic component 10, to optimize the heat transfer to electronic component 10 during the cooling process. A predetermined size of inner cavity 132 and/or outer cavity 134 is also based on characteristics of electronic component 10 and/or distinct portions of cooling apparatus 100 to aid in the cooling of electronic component 10, as discussed herein. Specifically, the size or dimensions (e.g., length, width, height) of inner cavity 132 and/or outer cavity 134 are based on, at least in part, thermal characteristics of electronic component 10, dimensions of electronic component 10, material characteristics of bottom wall 102, and/or dimensions of bottom wall 102. For example, a length (L) and/or width (W) of inner cavity 132 and/or outer cavity 134 is based on the heat, temperature, and/or thermal intensity generated by electronic component 10 during operation. In the example, as heat and/or thermal intensity of electronic component 10 increases during operation, so does the length (L) and/or width (W) of inner cavity 132. In this example, the length (L) and/or width (W) of outer cavity would decrease. Other thermal characteristics of electronic component 10 that determine the dimensions and/or size of inner cavity 132 and/or outer cavity 134 can also include a determined heat signature of electronic component 10 during operation. Additionally, the dimensions of inner cavity 132 and/or outer cavity 134 can be directly proportional to the dimensions of electronic component 10, such that as the dimensions of electronic component 10 increases, the dimensions of inner cavity 132 also increase. Material characteristics of bottom wall 102 also influence, at least in part, the predetermined size or dimensions of inner cavity 132 and/or outer cavity 134. For example, if bottom wall 102 is formed from a material having high thermal conductivity properties (e.g., copper), the length (L) and/or width (W) of inner cavity 132 are larger than the length (L) and/or width (W) of inner cavity 132 included in cooling apparatus where bottom wall 102 is formed from a material having lower thermal conductivity properties (e.g., aluminum). Furthermore, the dimensions (e.g., height (H), width (W), and/or length (L)) of inner cavity 132 and/or outer cavity 134 are based on, at least in part, the thickness (T) of bottom wall 102. In an example, as the thickness (T) of bottom wall 102 decreases, dimensions of inner cavity 132 increase to optimize the heat transfer to electronic component 10 during the cooling process. Any number or combination of the characteristics of electronic component 10 and/or distinct portions (e.g., bottom wall 102) of cooling apparatus 100 discussed herein are considered when determining the size and/or dimensions of inner cavity 132 and/or outer cavity 134. As discussed herein, these characteristics, at least in part, influence the size of inner cavity 132 and/or outer cavity 134, where the predetermined size of inner cavity 132 and/or outer cavity 134 optimizes heat transfer during the cooling process performed by cooling apparatus 100.

As discussed herein, cooling apparatus 100 includes various features, component, and/or configurations to optimize the cooling of electronic component 10 by substantially preventing heat (Q) from reaching and subsequently heating cooling fluid 110 to a temperature near or above a critical temperature threshold, which causes undesirable film boiling and/or dryout. Additionally discussed herein, cooling apparatus 100 includes various features, component, and/or configurations to ensure heat (Q) transferred and/or conducted through bottom wall 102 does interact with cooling fluid 110 at an undesirably low temperature so evaporation or the creation of cooling fluid vapor cannot occur. The predetermined size of inner cavity 132 and outer cavity 134 aid in this optimization.

Additionally, and similar to the predetermined size of inner cavity 132 and/or outer cavity 134, inner cavity 132 and outer cavity 134 include a predetermined, internal pressure (P) to optimize heat transfer during the cooling process performed by cooling apparatus 100. For example, inner cavity 132 includes a first internal pressure (P1), and outer cavity 134 includes a second internal pressure (P2) that is distinct and/or lower than the first internal pressure (P1) for inner cavity 132. The respective pressure within cavities 132, 134 determine, at least in part, a boiling/evaporation temperature for cooling fluid 110 and/or a critical temperature threshold where film boiling (and/or dryout) can occur with cooling fluid 110. More specifically, the lower the pressure of the respective cavities 132, 134, the lower the boiling/evaporation temperature for cooling fluid 110 and the lower the critical temperature threshold is for cooling fluid 110 formed in the cavity 132, 134. Outer cavity 134 includes a lower, second pressure (P2) because it is positioned adjacent to and/or not aligned with electronic component 10. That is, and as similarly discussed herein with respect to FIG. 2, outer cavity 134 does not receive heat (Q) that is as intense or high as the heat (Q) received in inner cavity 132 because the heat (Q) emitted by electronic component 10 travels through more of bottom wall 102 and/or a longer distance to reach outer cavity 134. In turn, more heat (Q) is absorbed within bottom wall 102 before reaching outer cavity 134. To ensure evaporation of cooling fluid 110 occurs during the cooling process, the pressure (P2) of outer cavity 134 is lowered (e.g., less than first pressure (P1) of inner cavity 132), which also lowers the boiling/evaporation temperature of cooling fluid 110 disposed therein. Forming cooling apparatus 100 to include distinct pressures (P1, P2) within respective cavities 132, 134 ensures heat (Q) is conducted through bottom wall 102 to cooling fluids 110 in respective cavities 132, 134, and evaporation can occur (e.g., temperature not below boiling/evaporation temperature), while eliminating or minimizing the risk of film boiling (e.g., temperature near or above a critical temperature threshold) and/or dryout, where applicable.

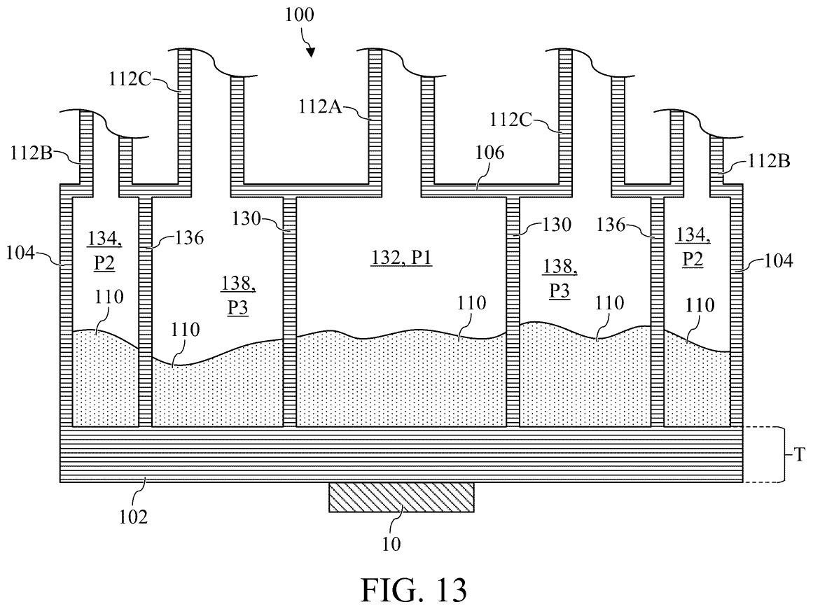

FIG. 13 shows another non-limiting example of cooling apparatus 100 including a plurality of distinct cavities. It is understood that similarly numbered and/or named components may function in a substantially similar fashion. Redundant explanation of these components has been omitted for clarity and/or brevity.

In the non-limiting example, cooling apparatus 100 also includes a distinct plurality of interior walls 136. Each of the distinct plurality of interior walls 136 are formed substantially perpendicular to bottom wall 102. More specifically, each distinct interior wall 136 extends from, is formed between, and/or oriented substantially perpendicular to bottom wall 102 and top wall 106, and each distinct interior wall 136 extends substantially perpendicular to each adjacent/abutting distinct interior wall 136. Additionally, the distinct plurality of interior walls 136 are surrounded by the plurality of exterior sidewalls 104 of cooling apparatus 100 and positioned between the plurality of sidewalls 104 and plurality of interior walls 130. In the non-limiting example, cooling apparatus 100 includes four distinct interior walls 136, each formed adjacent to and between corresponding sidewall 104, and interior wall 130. Each distinct interior wall 136 is also oriented substantially parallel to the adjacent sidewall 104 and interior wall 130, respectively. Similar to interior walls 130, it is understood that cooling apparatus 100 can include more or fewer distinct interior walls 136. The number of distinct interior walls 136 is dependent, at least in part on, the size/shape of electronic component 10 and/or the allotted space within the electronic device (not shown) that houses and/or receives cooling apparatus 100 and electronic component 10, respectively. Additionally, it is understood that cooling apparatus can include more or fewer distinct interior walls 136 than sidewalls 104 and/or interior walls 130.

Cooling apparatus 100 shown in FIG. 13 also includes an intermediary cavity 138. Intermediary cavity 138 is formed between inner cavity 132 and outer cavity 134. More specifically, intermediary cavity 138 is positioned adjacent to and substantially surrounds inner cavity 132, and intermediary cavity 138 is positioned adjacent to and is substantially surrounded by outer cavity 134. The plurality of interior walls 130 are positioned between and separate inner cavity 132, and intermediary cavity 138. Additionally, the distinct plurality of interior walls 136 are positioned between and separate intermediary cavity 138 and outer cavity 134 of cooling apparatus 100. In the non-limiting example, intermediary cavity 138 is defined by bottom wall 102, a portion of top wall 106, interior walls 130, and distinct interior walls 138. Cooling fluid 110 is also disposed within intermediary cavity 138 of cooling apparatus 100 and is used to cool electronic component 10. Intermediary cavity 138 is also in fluid communication with a third heatpipe(s) 112C. Similar to second heatpipes 112B, two distinct third heatpipes 112C are formed through top wall 106, opposite one another, and are both in fluid communication with intermediary cavity 138. In other non-limiting examples discussed herein, third heatpipe(s) 112C can be formed as a continuous rectangle hollow section (RHS) or square hollow section (SHS), where the RHS/SHS heatpipe 112C is in fluid communication with intermediary cavity 138. In combination with inner cavity 132 and/or outer cavity 134, intermediary cavity 138 includes a predetermined size or dimension to optimize heat transfer during the cooling process performed by cooling apparatus 100.

Intermediary cavity 138 of cooling apparatus 100 includes a third internal pressure (P3). Third internal pressure (P3) of intermediary cavity 138 is lower than first internal pressure (P1) of inner cavity 132, but greater than second internal pressure (P2) of outer cavity 134. Similar to the internal pressures (P1, P2) of inner cavity 132 and outer cavity 134, intermediary cavity 138 includes the predetermined, third internal pressure (P3) to optimize heat transfer during the cooling process performed by cooling apparatus 100.

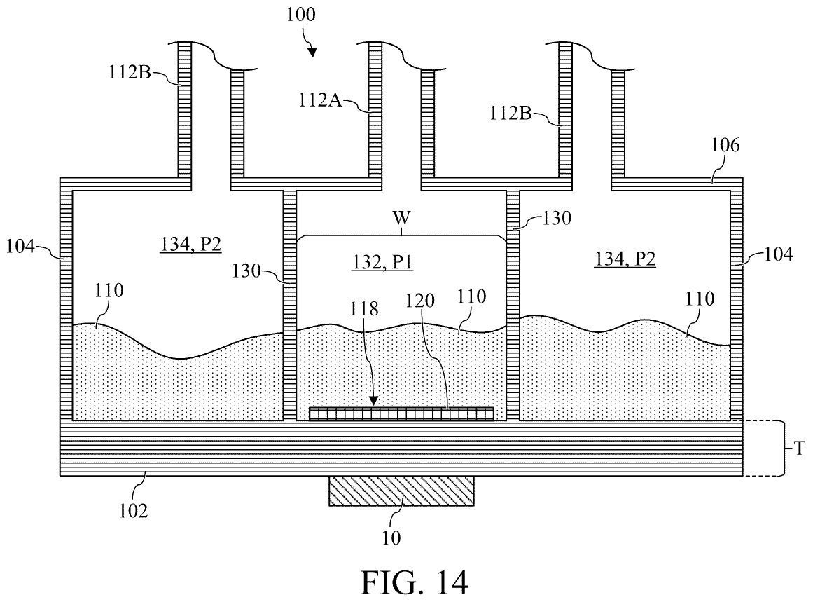

In the non-limiting example shown in FIG. 14, cooling apparatus 100 includes both a plurality of cavities 132, 134, as well as heat resistance components 118 formed therein. More specifically, inner cavity 132 of cooling apparatus 100 also includes heat resistance component 118, formed as patch 120, disposed therein and disposed directly over a portion of bottom wall 102. Patch 120 positioned within inner cavity 132 is also substantially aligned with electronic component 10. The combination of the plurality of cavities 132, 134, having predetermined internal pressures (P1, P2), and heat resistance component 118 increase the heat resistance of a portion of bottom wall 102 positioned over electronic component 10, and in turn optimize the cooling process of electronic component 10, as discussed herein with respect to FIGS. 1-13. Although only shown as disposing heat resistance component 118 within inner cavity 132, it is understood that inner cavity 132 and/or outer cavity 134 can include heat resistance component 118. In other examples, each cavity can include distinct heat resistance components 118 discussed herein with respect to FIGS. 1-10. For example, inner cavity 132 can include air gap 128 formed directly in a portion of bottom wall 102, while outer cavity 134 can include heat resistant paint 126 disposed directly over a portion of bottom wall 102.

Based on the above, examples of the present disclosure describe a cooling apparatus contacting an electronic component of an electronic device, the cooling apparatus comprising: a bottom wall directly contacting the electronic component; a plurality of sidewalls formed perpendicular to the bottom wall, the bottom wall and the plurality of sidewalls defining an internal cavity; a cooling fluid disposed within the internal cavity; and a heat resistance component positioned adjacent the cooling fluid and aligned with the electronic component, wherein the bottom wall is positioned between the heat resistance component and the electronic component. In an example, the heat resistance component is one of: positioned directly over at least a portion of the bottom wall, within the internal cavity, or directly embedded within the bottom wall, opposite to and aligned with the electronic component. In an example, the cooling fluid flows directly over the heat resistance component positioned directly over the portion of the bottom wall. In an example, the heat resistance component is formed as at least one of: a layer of heat resistant paint, a patch formed from a material having lower thermal conductivity properties than a material forming the bottom wall, or an air gap formed directly in the bottom wall, below the cooling fluid. In an example, the patch includes: a first portion in direct alignment the electronic device, the first portion including a first height; and a second portion formed adjacent and surrounding the first portion, the second portion including a second height less than the first height of the first portion. In an example, the second height of the second portion of the patch is tapered away from the first portion. In an example, the heat resistance component includes a predetermined size that is based on at least one of: thermal characteristics of the electronic component, dimensions of the electronic component, material characteristics of the bottom wall, or a thickness of the bottom wall. In an example, the heat resistance component is positioned proximate to and separated from the plurality of sidewalls.

Examples also describe a cooling apparatus contacting an electronic component of an electronic device, the cooling apparatus comprising: a bottom wall directly contacting the electronic component; a plurality of exterior sidewalls formed perpendicular to the bottom wall; a plurality of interior walls formed perpendicular to the bottom wall and surrounded by the plurality of exterior sidewalls; an inner cavity defined by the plurality of interior walls and the bottom wall, the inner cavity in direct alignment with the electronic device; an outer cavity defined by the plurality of exterior sidewalls and the bottom wall, the outer cavity surrounding the inner cavity; and a cooling fluid disposed within the inner cavity and the outer cavity. In an example, the plurality of interior walls is positioned between and separates the inner cavity and the outer cavity. In an example, the inner cavity includes a first internal pressure, and the outer cavity includes a second internal pressure, the second internal pressure lower than the first internal pressure. In an example, the cooling apparatus also includes a distinct plurality of interior walls formed perpendicular to the bottom wall, the distinct plurality of interior walls positioned between the plurality of exterior sidewalls and the plurality of interior walls; and an intermediary cavity defined by the plurality of interior walls, the bottom wall, and the distinct plurality of interior walls, the intermediary cavity surrounding the inner cavity and surrounded by the outer cavity. In an example, the intermediary cavity includes a third internal pressure, the third internal pressure is lower than the first internal pressure of the inner cavity, and greater than the second internal pressure of the outer cavity. In an example, the cooling fluid is disposed within the intermediary cavity. In an example, the inner cavity includes a predetermined size that is based on at least one of: thermal characteristics of the electronic component, dimensions of the electronic component, material characteristics of the bottom wall, or a thickness of the bottom wall. In an example, the cooling apparatus also includes a first heatpipe in fluid communication with the inner cavity; and a second heatpipe in fluid communication with the outer cavity.

Examples also describe a cooling apparatus contacting an electronic component of an electronic device, the cooling apparatus comprising: a bottom wall directly contacting the electronic component; a plurality of sidewalls formed perpendicular to the bottom wall, the plurality of sidewalls and the bottom wall defining an internal cavity; a means for increasing heat resistance for the bottom wall aligned with the electronic component, the bottom wall positioned between the means for increasing heat resistance and the electronic component; and cooling means disposed over the bottom wall and positioned within the internal cavity. In an example, the means for increasing the heat resistance of the bottom wall is one of: positioned directly over at least a portion of the bottom wall, within the internal cavity defined by the bottom wall and the plurality of sidewalls, or directly embedded within the bottom wall, opposite to and aligned with the electronic component. In an example, the cooling apparatus also includes a means for separating the internal cavity defined by the plurality of sidewalls and the bottom wall, wherein the plurality of sidewalls surround the means for separating the internal cavity. In an example, the means for increasing heat resistance includes: a first means for increasing heat resistance for the bottom wall in direct alignment with the electronic device, the first means for increasing the heat resistance for the bottom wall defined by the means for separating the internal cavity; and a second means for increasing heat resistance for the bottom wall surrounding the first means for increasing the heat resistance, the second means for increasing the heat resistance of the bottom wall defined by the plurality of exterior sidewalls, the bottom wall, and the means for separating the internal cavity, wherein the cooling means are disposed within the first means for increasing the heat resistance for the bottom wall and the second means for increasing the heat resistance for the bottom wall.

The foregoing drawings show some of the processing associated according to several examples of this disclosure. In this regard, each drawing or block within a flow diagram of the drawings represents a process associated with examples of the method described. It should also be noted that in some alternative implementations, the acts noted in the drawings or blocks may occur out of the order noted in the figure or, for example, may in fact be executed substantially concurrently or in the reverse order, depending upon the act involved. Also, one of ordinary skill in the art will recognize that additional blocks that describe the processing may be added.

The terminology used herein is for the purpose of describing particular examples only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” and/or “substantially” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The example was chosen and described in order to best explain the principles of the disclosure and the practical application, and to enable others of ordinary skill in the art to understand the disclosure for various example with various modifications as are suited to the particular use contemplated.

What is claimed is:

1. A cooling apparatus contacting an electronic component of an electronic device, the cooling apparatus comprising:
a bottom wall directly contacting the electronic component;
a plurality of sidewalls formed perpendicular to the bottom wall, the bottom wall and the plurality of sidewalls defining an internal cavity;
a cooling fluid disposed within the internal cavity; and
a heat resistance component positioned adjacent the cooling fluid and aligned with the electronic component,
wherein the bottom wall is positioned between the heat resistance component and the electronic component.

2. The cooling apparatus of claim 1, wherein the heat resistance component is one of:
positioned directly over at least a portion of the bottom wall, within the internal cavity, or
directly embedded within the bottom wall, opposite to and aligned with the electronic component.

3. The cooling apparatus of claim 2, wherein the cooling fluid flows directly over the heat resistance component positioned directly over the portion of the bottom wall.

4. The cooling apparatus of claim 1, wherein the heat resistance component is formed as at least one of:
a layer of heat resistant paint,
a patch formed from a material having lower thermal conductivity properties than a material forming the bottom wall, or
an air gap formed directly in the bottom wall, below the cooling fluid.

5. The cooling apparatus of claim 4, wherein the patch includes:
a first portion in direct alignment the electronic device, the first portion including a first height; and
a second portion formed adjacent and surrounding the first portion, the second portion including a second height less than the first height of the first portion.

6. The cooling apparatus of claim 5, wherein the second height of the second portion of the patch is tapered away from the first portion.

7. The cooling apparatus of claim 1, wherein the heat resistance component includes a predetermined size that is based on at least one of:
thermal characteristics of the electronic component,
dimensions of the electronic component,
material characteristics of the bottom wall, or
a thickness of the bottom wall.

8. The cooling apparatus of claim 1, wherein the heat resistance component is positioned proximate to and separated from the plurality of sidewalls.

9. A cooling apparatus contacting an electronic component of an electronic device, the cooling apparatus comprising:
a bottom wall directly contacting the electronic component;
a plurality of exterior sidewalls formed perpendicular to the bottom wall;
a plurality of interior walls formed perpendicular to the bottom wall and surrounded by the plurality of exterior sidewalls;
an inner cavity defined by the plurality of interior walls and the bottom wall, the inner cavity in direct alignment with the electronic device;
an outer cavity defined by the plurality of exterior sidewalls and the bottom wall, the outer cavity surrounding the inner cavity; and
a cooling fluid disposed within the inner cavity and the outer cavity.

10. The cooling apparatus of claim 9, wherein the plurality of interior walls is positioned between and separates the inner cavity and the outer cavity.

11. The cooling apparatus of claim 9, wherein the inner cavity includes a first internal pressure, and the outer cavity includes a second internal pressure, the second internal pressure lower than the first internal pressure.

12. The cooling apparatus of claim 11, further comprising:
a distinct plurality of interior walls formed perpendicular to the bottom wall, the distinct plurality of interior walls positioned between the plurality of exterior sidewalls and the plurality of interior walls; and
an intermediary cavity defined by the plurality of interior walls, the bottom wall, and the distinct plurality of interior walls, the intermediary cavity surrounding the inner cavity and surrounded by the outer cavity.

13. The cooling apparatus of claim 12, wherein the intermediary cavity includes a third internal pressure, the third internal pressure is lower than the first internal pressure of the inner cavity, and greater than the second internal pressure of the outer cavity.

14. The cooling apparatus of claim 12, wherein the cooling fluid is disposed within the intermediary cavity.

15. The cooling apparatus of claim 9, wherein the inner cavity includes a predetermined size that is based on at least one of:
thermal characteristics of the electronic component,
dimensions of the electronic component,
material characteristics of the bottom wall, or
a thickness of the bottom wall.

16. The cooling apparatus of claim 9, further comprising:
a first heatpipe in fluid communication with the inner cavity; and
a second heatpipe in fluid communication with the outer cavity.

17. A cooling apparatus contacting an electronic component of an electronic device, the cooling apparatus comprising:
a bottom wall directly contacting the electronic component;
a plurality of sidewalls formed perpendicular to the bottom wall, the plurality of sidewalls and the bottom wall defining an internal cavity;
a means for increasing heat resistance for the bottom wall aligned with the electronic component, the bottom wall positioned between the means for increasing heat resistance and the electronic component; and
cooling means disposed over the bottom wall and positioned within the internal cavity.

18. The cooling apparatus of claim 17, wherein the means for increasing the heat resistance of the bottom wall is one of:
positioned directly over at least a portion of the bottom wall, within the internal cavity defined by the bottom wall and the plurality of sidewalls, or
directly embedded within the bottom wall, opposite to and aligned with the electronic component.

19. The cooling apparatus of claim 17, further comprising:
a means for separating the internal cavity defined by the plurality of sidewalls and the bottom wall, wherein the plurality of sidewalls surround the means for separating the internal cavity.

20. The cooling apparatus of claim 19, wherein the means for increasing heat resistance includes:
a first means for increasing heat resistance for the bottom wall in direct alignment with the electronic device, the first means for increasing the heat resistance for the bottom wall defined by the means for separating the internal cavity; and
a second means for increasing heat resistance for the bottom wall surrounding the first means for increasing the heat resistance, the second means for increasing the heat resistance of the bottom wall defined by the plurality of exterior sidewalls, the bottom wall, and the means for separating the internal cavity,
wherein the cooling means are disposed within the first means for increasing the heat resistance for the bottom wall and the second means for increasing the heat resistance for the bottom wall.
